(19) United States
(12) Patent Application Publication
(10) Pub. No.: US 2009/0104377 A1
(43) Pub. Date: Apr. 23, 2009

(54) Vapor deposition head apparatus and method of coating by vapor deposition

(76) Inventors: Hidehiro Yoshida, Osaka (JP); Seiji Nakashima, Nara (JP)

Correspondence Address: WENDEROTH, LIND & PONACK L.L.P., 1030 15th Street, N.W., Suite 400 East, Washington, DC, 20005-1503, US

(21) Appl. No.: 11/919,665

(22) PCT Filed: Aug. 28, 2006
(86) PCT No.: PCT/JP2006/316874

§ 371 Date: Feb. 6, 2008

(30) Foreign Application Priority Data
Aug. 29, 2005 (JP) 2005-247098

(51) Int. Cl. C23C 16/455

(52) U.S. Cl. 427/593; 118/715

(57) ABSTRACT

A method of coating by vapor deposition including heating a material-heating cell provided in a chamber and having a nozzle part at its one end, for holding a solid material, supplying a fluid from the other end side of the chamber toward the nozzle part of the chamber to guide the material vaporized from the heated material-heating cell to the nozzle part to discharge the material from the nozzle part, and blowing a gas for controlling a vapor-deposition material straight movement, outside the nozzle part of the chamber toward the tip of the nozzle part to control the material discharged from the nozzle part so that the material can move straight ahead.

### TECHNICAL FIELD

The present invention relates to a vapor deposition head apparatus and a method of coating by vapor deposition, for coating an object to be coated such as a substrate with an organic material, an inorganic material, or a material obtained by mixing an organic material and an inorganic material, by vapor deposition.

### BACKGROUND ART

In recent years, organic EL (Electro Luminescence) devices or organic semiconductor devices using low molecular organic materials have been mainly produced by vapor deposition, and on the other hand, organic EL devices or organic semiconductor devices using high molecular organic materials have been mainly produced by an ink-jet method. In the case of using a low molecular organic material, a coating film of the material is formed by vapor deposition in a vacuum chamber with a high degree of accuracy. In particular, a low molecular organic material exhibits higher performance as an organic EL material than a high molecular organic material.

For example, Patent Document 1 describes a method in which an ionized organic material and an ionized inorganic material are alternately vapor-deposited on a substrate to improve the orientation of the organic material.

However, in the case of using this method, the organic material and the inorganic material are vapor-deposited on the entire substrate, and therefore material use efficiency can be considered to be very low.

Further, in the case of a high molecular material, an ink-jet method is mainly used. The ink-jet method is a method in which only the required amount of material is applied onto an area requiring the material, and therefore material use efficiency is very high. For this reason, the ink-jet method has recently been drawing attention as a low-cost production method.

Further, Patent Document 2 describes a method for producing a semiconductor device using a high molecular material by coating an oriented surface with a solvent in which a high molecular material is dissolved. Also in the case of using this method, material use efficiency is very high.

However, high molecular materials are inferior in electrical mobility to low molecular materials, and therefore, under the present circumstances, high molecular EL devices are particularly inferior in luminous efficiency to low molecular EL devices.

Patent Document 1: Unexamined Japanese Patent Publication No. 08-176803

Patent Document 2: Unexamined Japanese Patent Publication No. 2004-31458

### DISCLOSURE OF INVENTION

### Issues to be Solved by the Invention

In the case of producing a device by vapor deposition of a low molecular material, the material spreads throughout the chamber, and therefore the amount of the material which can reach a target substrate is very small. Even when the material reaches the substrate, material use efficiency is very low because patterning on the substrate is performed by, for example, photolithography.

On the other hand, the ink-jet method used for high molecular materials is a method in which only the required amount of material is applied onto an area requiring the material, but high molecular organic EL devices or the like produced by the ink-jet method are inferior in light-emitting properties and the like to low molecular organic EL devices.

The reason why the ink-jet method cannot be used for low molecular materials is that, if the method is used for a low molecular material, the low molecular material is partially crystallized when it is dried after coating, and therefore the boundary between crystalline particles interferes with electric migration, so that an obtained coating film of the low molecular material is not uniform in its characteristics.

In view of the issues associated with the background art described above, it is an object of the present invention to provide a vapor deposition head apparatus and a method of coating by vapor deposition capable of applying a high-performance low-molecular material by vapor deposition even at atmospheric pressure.

### Means for Solving the Subject

In order to achieve the above object, the present invention has the following constitution.

According to the present invention, there is provided a method/system capable of directly forming a pattern of a low molecular material by vapor-deposition coating even at atmospheric pressure by heating a material containing the low molecular material in a small chamber in order to coat the low molecular material with high efficiency, controlling the charge of the material vaporized by heating, and reducing the pressure around the tip of a nozzle which is in contact with the air. According to the proposed method, it is possible to control the diameter of the material ejected from the nozzle by applying the same electric potential as the charge of the vaporized material to an area in the vicinity of the tip of the nozzle. Further, by applying to a substrate an electric potential opposite to that applied to the material, it is possible to accelerate the energy of vapor-deposited molecules and to coat the substrate with the material even under low vacuum conditions.

More specifically, according to a first aspect of the present invention, there is provided a vapor deposition head apparatus comprising:

a chamber having a nozzle part at its one end;

a material-heating cell, provided in the chamber, for holding a solid material;

a resistance-heating part for heating the material-heating cell;

a fluid-supplying device connected to an other end of the chamber to supply a fluid from an other end side of the chamber into the chamber to guide the material vaporized from the material-heating cell heated by the resistance-heating part to the nozzle part of the chamber to discharge the material from the nozzle part; and

an air-blowing part for blowing a gas for controlling vapor deposition material straight movement, outside the nozzle part of the chamber toward a tip of the nozzle part to control the material discharged from the nozzle part so that the material can move straight ahead.

According to a second aspect of the present invention, there is provided the vapor deposition head apparatus according to the first aspect, further comprising:

an ionizer for ionizing the solid material vaporized from the material-heating cell heated by the resistance-heating part, the ionizer being provided between the nozzle part and the material-heating cell; and

an electric potential-applying part for applying an electric potential different from that of a charge of the ionized material to an object onto which the material discharged from the nozzle part of the chamber is to be vapor-deposited.

According to a third aspect of the present invention, there is provided the vapor deposition head apparatus according to the first or second aspect, wherein the electric potential-applying part applies the same electric potential as the charge of the ionized material to the chamber.

According to a fourth aspect of the present invention, there is provided the vapor deposition head apparatus according to the first or second aspect, further comprising a shutter for opening and closing an aperture of the nozzle part of the chamber.

According to a fifth aspect of the present invention, there is provided the vapor deposition head apparatus according to the third aspect, further comprising a shutter for opening and closing an aperture of the nozzle part of the chamber.

According to a sixth aspect of the present invention, there is provided the vapor deposition head apparatus according to the first aspect, wherein the material-heating cell functions as a first material-heating cell for holding an organic material as the solid material and the resistance-heating part functions as a first resistance-heating part for heating the first material-heating cell to vaporize the organic material,

the vapor deposition head apparatus further comprising:

a second material-heating cell provided in the chamber for holding an inorganic material as the solid material; and

a second resistance-heating part for heating the second material-heating cell, wherein

the second material-heating cell is heated by the second resistance-heating part to vaporize the inorganic material, and

the vaporized organic material and the vaporized inorganic material are mixed at a certain ratio in the chamber and are then discharged from the nozzle part of the chamber.

According to a seventh aspect of the present invention, there is provided a method of coating by vapor deposition comprising:

heating a material-heating cell provided in a chamber, and having a nozzle part at its one end, for holding a solid material; and

supplying a fluid from an other end side of the chamber toward the nozzle part of the chamber to guide the material vaporized from the heated material-heating cell to the nozzle part to discharge the material from the nozzle part, blowing a gas for controlling a vapor-deposition material straight movement, outside the nozzle part of the chamber toward a tip of the nozzle part to control the material discharged from the nozzle part so that the material can move straight ahead.

According to an eighth aspect of the present invention, there is provided the method of coating by vapor deposition according to the seventh aspect, wherein when the material vaporized from the material-heating cell is discharged from the nozzle part, the solid material vaporized from the heated material-heating cell is ionized between the nozzle part and the material-heating cell and an electric potential different from that of a charge of the ionized material is applied to an object onto which the material discharged from the nozzle part of the chamber is to be vapor-deposited.

According to a ninth aspect of the present invention, there is provided the method of coating by vapor deposition according to the seventh or eighth aspect, wherein when the material vaporized from the material-heating cell is discharged from the nozzle part, the same electric potential as the charge of the ionized material is applied to the chamber.

According to a 10th aspect of the present invention, there is provided the method of coating by vapor deposition according to the seventh or eighth aspect, wherein when the material vaporized from the material-heating cell is discharged from the nozzle part, start and stop of discharge of the material from the nozzle part is controlled by opening and closing an aperture of the nozzle part of the chamber using a shutter.

According to an 11th aspect of the present invention, there is provided the method of coating by vapor deposition according to the ninth aspect, wherein when the material vaporized from the material-heating cell is discharged from the nozzle part, start and stop of discharge of the material from the nozzle part is controlled by opening and closing an aperture of the nozzle part of the chamber using a shutter.

According to a 12th aspect of the present invention, there is provided the method of coating by vapor deposition according to the seventh aspect, wherein when the material-heating cell for holding the solid material is heated, an organic material and an inorganic material are heated, and when the material vaporized from the material-heating cell is discharged from the nozzle part, the organic material vaporized by heating and the inorganic material vaporized by heating are mixed at a certain ratio in the chamber and discharged from the nozzle part of the chamber.

### EFFECTS OF THE INVENTION

As described above, a device formation technique according to the vapor deposition head apparatus and the method of coating by vapor deposition according to the present invention can directly coat an object to be coated, such as a substrate, with a high-performance low molecular material by vapor deposition even at atmospheric pressure without lowering material use efficiency. Further, by controlling a voltage applied to the nozzle part, it is also possible to control the discharge diameter of the material discharged from the tip of the nozzle part.

### BRIEF DESCRIPTION OF DRAWINGS

These and other aspects and features of the present invention will become clear from the following description taken in conjunction with the preferred embodiments thereof with reference to the accompanying drawings, in which:

FIG. 1A is a structural diagram, with partially seen-through, of a vapor deposition head apparatus according to a first embodiment of the present invention;

FIG. 1B is a perspective view, with partially seen-through, of a shutter mechanism of the vapor deposition head apparatus according to the first embodiment of the present invention;

FIG. 1C is an enlarged sectional view of a nozzle part of the vapor deposition head apparatus according to the first embodiment of the present invention;

FIG. 1D is an enlarged sectional view of an alternative nozzle part of the vapor deposition head apparatus according to the first embodiment of the present invention;

FIG. 1E is an enlarged sectional view of a resistance-heating part of the vapor deposition head apparatus according to the first embodiment of the present invention;

FIG. 2 is a flowchart of a vapor-deposition coating operation using the vapor deposition head apparatus according to the first embodiment of the present invention;

FIG. 3 is a schematic structural view of a vapor deposition head apparatus according to a variation of the first embodiment of the present invention for use in vapor deposition of a mixture of both organic and inorganic materials (some components that are the same as those shown in FIG. 1A are not shown);

FIG. 4A is a schematic structural view of a vapor deposition head apparatus according to a second embodiment of the present invention (some components that are the same as those shown in FIG. 1A are not shown);

FIG. 4B is a view for explaining a state where a metal mask is arranged in the vapor deposition head apparatus according to the second embodiment of the present invention;

FIG. 5 is a view for explaining a state where RGB pixels are formed through coating so as to be adjacent to one other; and

FIG. 6 is a view showing a plurality of vapor deposition heads.

### BEST MODE FOR CARRYING OUT THE INVENTION

Before the description of the present invention proceeds, it is to be noted that like parts are designated by like reference numerals throughout the accompanying drawings.

Hereinbelow, preferred embodiments of the present invention will be described with reference to the drawings.

### First Embodiment

A vapor deposition head apparatus according to a first embodiment of the present invention and a method of coating by vapor deposition which can be carried out by the head apparatus will be described.

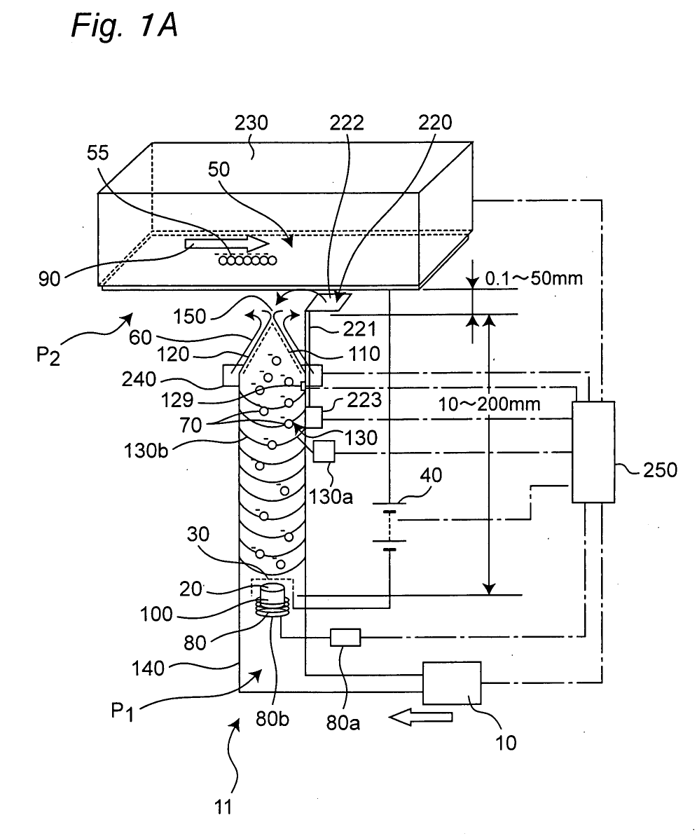

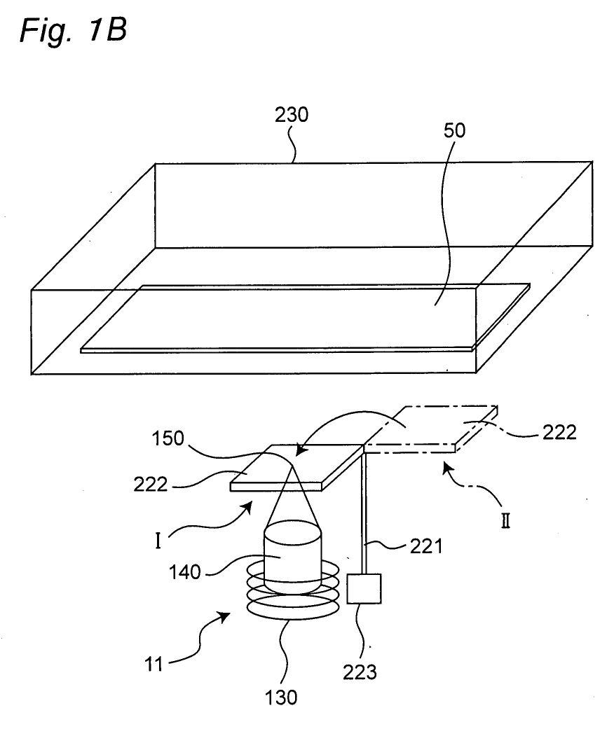

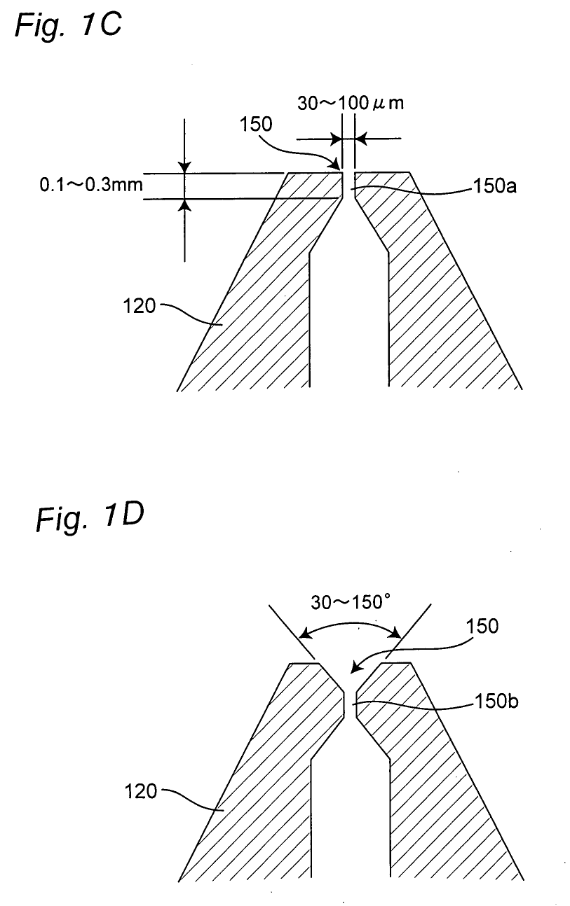

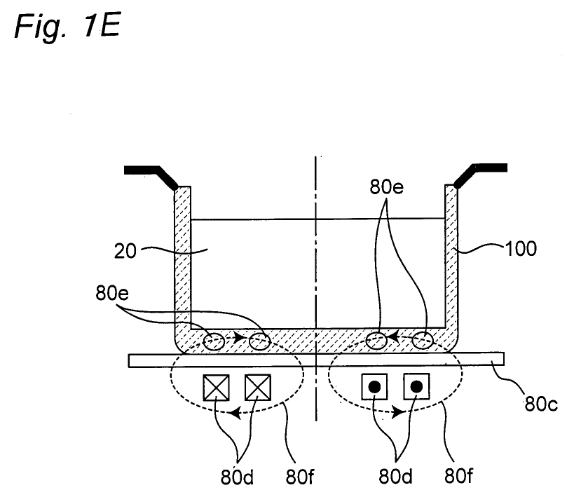

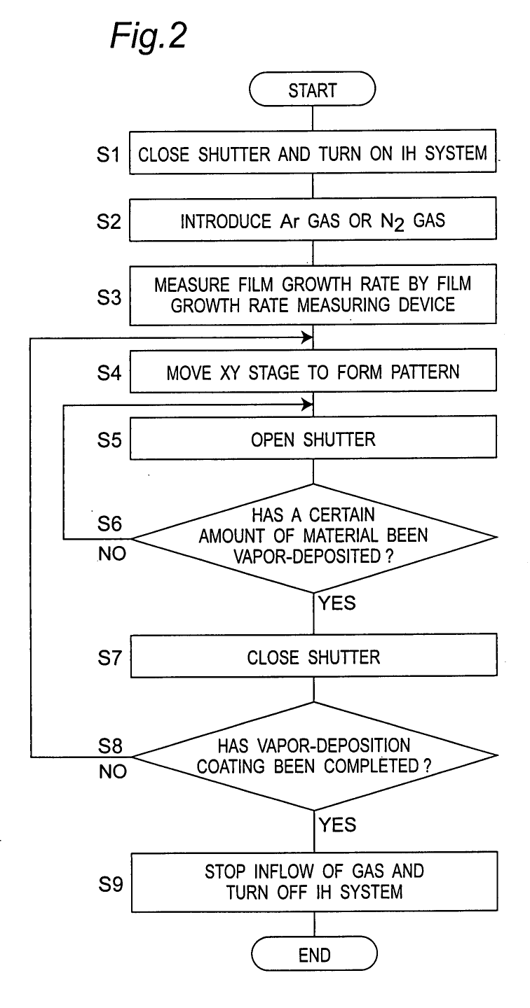

FIGS. 1A to 2 are views for explaining a vapor deposition head apparatus 11 according to the first embodiment of the present invention.

As shown in FIG. 1A, the vapor deposition head apparatus 11 includes a cylindrical chamber 140, a material-heating cell 100, a resistance heater 80 used as an example of a resistance-heating part, an ionizer 30, a power supply 40 used as an example of an electric potential-applying part, an air-blowing part 240, a side surface resistance-heating part 130, a fluid-supplying device 10, a shutter mechanism 220, an XY stage device 230, and a control part 250, and is intended to be used to coat a substrate 50 as one example of an object to be coated, with a high-performance low-molecular material by vapor deposition even at atmospheric pressure to form a coating film of the low-molecular material.

The cylindrical chamber 1 has a tapered conical cylindrical nozzle part 120 at its one end (in FIG. 1A, at its upper end). As examples of the material of the chamber 1, iron (SS400), stainless steel (SUS304), aluminum (A5052), or cast metals (cast aluminum will suffice because high vacuum is not necessary) can be used. The hole diameter of the nozzle part 120 can be formed by machining using picosecond laser or electric discharging.

The nozzle part 120 has a nozzle tip portion 150 at its end, and the nozzle tip portion 150 has a narrow opening. One example of the specific shape of the nozzle tip portion 150 is shown in FIG. 1C. As shown in FIG. 1C, when the size (diameter) of a minimum gap 150a of the nozzle tip portion 150 is set to 30 to 100 μm and the length of the minimum gap 150a in the axial direction is set to 0.1 to 0.3 mm, a uniformity of ±10% can be ensured. Alternatively, as shown in FIG. 1D, a larger opening angle of a minimum gap 150b makes uniformity higher. For example, when the opening angle is set to 30° to 150°, a uniformity of ±5% can be ensured.

The material-heating cell 100 is arranged in the chamber 140, and is constructed as a container having a circular shape capable of holding a solid material 20 such as a powder material. The distance between the tip of the nozzle part 120 and the material-heating cell 100 is preferably, for example, 10 mm or more but 200 mm or less from the viewpoint of controlling coating with good accuracy.

The resistance heater 80 used as an example of the resistance-heating part includes a heating power supply 80a and a resistance portion 80b for generating heat by electric current from the heating power supply 80a. The resistance portion 80b is arranged around the material-heating cell 100 provided in the chamber 140 to generate heat and apply the heat to the material-heating cell 100 to heat the powder material 20 contained in the material-heating cell 100 to, for example, 200 to 400° C.

In order to vapor-deposit an organic material at atmospheric pressure, the heating temperature of the material is preferably in the above range from a practical viewpoint. For example, the temperature at which Alq₃ that is a representative example of organic materials vaporizes is 300° C.

The resistance portion 80b may be built into the material-heating cell 100. An example of the resistance portion 80b includes an IH (induction heating) system as shown in FIG. 1E. In the case of using such an IH system, a top plate 80c is provided under the bottom surface of the material-heating cell 100, and an IH heating coil 80d is further provided under the bottom surface of the top plate 80c. The IH heating coil 80d generates an eddy current 80e in the bottom surface of the material-heating cell 100 to heat the material 20 contained in the material-heating cell 100. It is to be noted that a reference numeral 80f in FIG. 1E designates a line of magnetic force. The calorific value W of the IH heating coil 80d is represented by the equation W=I²×R, where I represents an eddy current and R represents the electric resistivity of the bottom surface of the material-heating cell 100.

The ionizer 30 is arranged on the nozzle part 120 side of the material-heating cell 100 in the chamber 140. The power supply 40 applies a predetermined voltage to the ionizer 30 to ionize the powder material 20.

The power supply 40 used as an example of the electric potential-applying part applies a predetermined voltage across the ionizer 30 and chamber 140, and a substrate 50 made of glass or film serving as one example of an object to be coated, which is arranged so as to be opposed to the nozzle part 120 to apply an electric potential different from that of the ionized material 20 to the substrate 50. By the power supply 40, the nozzle part 120 has the same electric charge in sign as the ionized material 20, so that the ionized material 20 is less likely to be attached to the chamber 140 such as the nozzle part 120, which will be described later.

The air-blowing part 240 has a plurality of nozzles provided outside the chamber 140 along the outer surface of the chamber 140 to blow a gas for controlling a vapor-deposition material straight movement (e.g., air) along the outer surface of the chamber 140 toward the nozzle tip portion 150 of the nozzle part 120 as shown by the arrow 60 shown in FIG. 1A to generate a flow of fluid along the outer surface of the nozzle tip portion 150 of the chamber 140 to guide the material 20 sprayed from the nozzle tip portion 150 so that the material 20 can move straight ahead toward the substrate 50.

The side surface resistance-heating part 130 includes a heating power supply 130a and a resistance portion 130b for generating heat by electric current from the heating power supply 130a. The resistance portion 130b is provided around the outer surface of the chamber 140 between the material-heating cell 100 and the nozzle tip portion 150 of the nozzle part 120 to generate heat and apply the heat to the side surface of the chamber 140 between the material-heating cell 100 and the nozzle tip portion 150 of the nozzle part 120 to heat it to, for example, 100 to 200° C. If the side surface of the chamber 140 is heated to higher than 200° C., there is a possibility that materials or electric wires used are adversely affected. In addition, the material 20 attached to the chamber 140 can be sufficiently vaporized by heating it to 100° C. or higher but 200° C. or less. For example, the heating temperature of the material-heating cell 100 (e.g., 200 to 400° C.) is preferably higher than the heating temperature of the chamber 140 (e.g., 100 to 200° C.).

The fluid-supplying device 10 is connected to the other end of the chamber 140 (in FIG. 1A, the lower end of the chamber 140) that is opposite to the one end of the chamber 140 where the nozzle part 120 is provided (in FIG. 1A, the upper end of the chamber 140), to flow the heated material 20, that is, to flow a vapor deposition material-guiding fluid (e.g., a vapor deposition material-guiding gas) from the material-heating cell-100-side of the chamber 140 toward the nozzle part 120, so that the fluid itself accelerates the flow speed of ions to reliably form a vapor-deposited coating on the substrate 50. Therefore, the pressure P₁ in the chamber 140 is preferably higher than the pressure P₂ around the nozzle part 120 outside the chamber 140. By setting P₁>P₂, it is possible to forcibly blow the vapor-deposition material. If the pressure P₁ and the pressure P₂ do not satisfy P₁>P₂, the rate of forming a coating film of the vapor-deposition material is lowered. For example, the pressure in the chamber 140 is preferably 10⁵ Pa (750 torr) or higher but 3.3×10³ Pa (25 torr) or less. The flow rate of the fluid is preferably, for example, 2 sccm or higher but a few tens of sccm or less. As examples of the fluid, Ar gas or N₂ gas can be used. In order to vapor-deposit an organic material at atmospheric pressure, the pressure in the chamber 140 and the flow rate of the fluid are preferably within the above ranges from a practical viewpoint. For example, in the case of Alq₃ that is a representative example of organic materials, judging from the vapor pressure curve of Alq₃, Alq₃ can be vapor-deposited by setting the pressure in the chamber 140 and the flow rate of the fluid to a value within the above ranges.

By flowing a fluid, such as a gas, supplied by the fluid-supplying device 10 from the material-heating cell-100-side of the chamber 140 toward the nozzle part 120, the kinetic energy of the heated material 20 can be increased by the gas. By doing so, without provision of the ionizer 30, ion assist can be sometimes omitted. In a case where the ionizer 30 is provided for ion assist, the heated material 20 can have higher kinetic energy, and therefore it is possible to carry out vapor deposition without reducing the pressure in the chamber 140. In addition, after the material 20 is discharged from the nozzle tip portion to the outside, the material 20 is less likely to flow along the outer surface of the nozzle tip portion, so that a high precision pattern can be formed.

The shutter mechanism 220 is provided close to the nozzle tip portion 150 of the nozzle part 120 so that the nozzle tip portion 150 can be opened or closed by a shutter 222. The shutter 222 is made to have the same electric charge in sign as that of the ionized material 20, so that the ionized material 20 is less likely to attach not only to the chamber 140 such as the nozzle part 120 but also to the shutter 222. More specifically, as shown in FIG. 1B, the shutter mechanism 220 is provided close to the nozzle tip portion 150 of the nozzle part 120, and has a support axis 221 whose one end is rotatably supported and the other end is fixed to the shutter 222. By rotating forwardly and reversely the support axis 221 using a motor 223, the shutter 222 can be moved between a closed position I where the nozzle tip portion 150 of the nozzle part 120 is closed by the shutter 222 and an open position II where the nozzle tip portion 150 of the nozzle part 120 is opened by moving the shutter 222 away from the nozzle tip portion 150. It is to be noted that when the shutter 222 is located in the closed position I, the nozzle tip portion 150 of the nozzle part 120 is not completely closed by the shutter 222, but a slight clearance is provided between both the members to allow the fluid supplied from the fluid-supplying device 10 into the chamber 140 to leak out of the chamber 140 to prevent the pressure in the chamber 140 from becoming higher than a predetermined pressure.

The XY stage device 230 holds the substrate 50 by suction or by using a chuck, and the axis of the XY stage device 230 is orthogonal to the axis of the chamber 140 to allow the substrate 50 to move in the X and Y directions which are orthogonal to each other. In FIG. 1A, the substrate 50 can be moved in the X and Y directions with respect to the vapor deposition head apparatus 11, but the present invention is not limited thereto. For example, the substrate 50 may be fixed to move the vapor deposition head apparatus 11 in the X and Y directions with respect to the substrate 50. In this case, the vapor deposition head apparatus 11 is supported by the XY stage device.

The control part 250 controls the operation of each of the resistance heater 80, the ionizer 30 and the power supply 40, the air-blowing part 240, the side surface resistance-heating part 130, the fluid-supplying device 10, the shutter mechanism 220, and the XY stage device 230.

According to the structure described above, the solid material 20, such as an organic material, contained in the material-heating cell 100 heated by the resistance heater 80 is heated and vaporized in the material-heating cell 100, and is then ionized by the ionizer 30. In FIG. 1A, single-step ionization is carried out using one ionizer 30, but multi-step ionization may be carried out using a plurality of ionizers 30 provided toward the nozzle tip portion 150 to increase an ionization rate. Charged molecules 70 of the material 20 ionized by the ionizer 30 are accelerated by the electric charge between the charged molecules 70 and the substrate 50, and are less likely to come into collision with the nozzle part 120. This is because, as described above, the power supply 40 makes the nozzle part 120 have the same electric charge in sign as that of the ionized charged molecules 70. Even when the charged molecules 70 are attached to the side surface of the chamber 140 in the course of vapor deposition, they are heated by the side surface resistance-heating part 130 provided on the side surface of the chamber 140, and therefore can again vaporize from the side surface of the chamber 140, so that the accumulation of the charged molecules 70 on the side surface of the chamber 140 is effectively prevented.

The charged molecules 70 move upwardly from the material-heating cell 100 toward the nozzle tip portion 150 and then reach the substrate 50 having electric charge opposite to that of the charged molecules 70. The pressure around the nozzle tip portion 150 of the nozzle part 120 is reduced by the gas blown from the air-blowing part 240 along the outer surface of the nozzle part 120. It is preferred that the gas contains no oxygen nor moisture because an organic material is sensitive to oxygen and moisture. For example, dry nitrogen gas or an inert gas may be used.

The process of coating by the vapor deposition head apparatus 11 having the structure described above will be described below with reference to the flowchart of the process of coating by vapor deposition shown in FIG. 2. This process is controlled by the control part 250.

First, in step S1, the resistance heater 80 is turned on in a state where the shutter 222 is located in the closed position II to start heating of the material 20 contained in the material-heating cell 100.

Then, in step S2, Ar gas or N₂ gas is allowed to flow into the chamber 140 by the fluid-supplying device 10. The Ar gas or N₂ gas is discharged together with the heated material 20 from the nozzle tip portion 150 of the nozzle part 120, and then the heated material 20 is vapor-deposited on the shutter 222.

Then, in step S3, the film growth rate of a thin film of the material 20 formed on the substrate 50 by vapor deposition is measured. The film growth rate is measured using, for example, a film growth rate-measuring device 129 arranged close to the nozzle part 120 in the chamber 140 and connected to the control part 250. In the case of using the film growth rate-measuring device 129, for example, a metal plate detachably connected to a piezoelectric element is prepared, and when the natural frequency of the metal plate as measured by vibrating the piezoelectric element is changed due to the charged molecules 70 of the organic material 20 deposited on the metal plate, an amount of change in natural frequency of the metal plate is converted into mass by a film thickness monitor part (film thickness-computing part) to calculate the thickness of a coating film vapor-deposited on the metal plate. If a too large amount of the organic material 20 is deposited on the metal plate, the metal plate may be changed to another one. During the coating of the metal plate with the material 20 by vapor deposition, the film thickness monitor part (film thickness-computing part) determines whether the amount of change in natural frequency of the metal plate has become constant or not. In general, the film growth rate is unstable just after the beginning of heating of the material, and therefore it is necessary to allow a certain time to elapse.

When the film thickness monitor part (film thickness-computing part) determines that the amount of change in natural frequency of the metal plate has become constant, it can be considered that the film growth rate has become stable. Then, a characteristic test is carried out as a preparation to form a thin film on the substrate 50 as a product by vapor deposition. In the characteristic test, the shutter 222 is opened to form a coating film by vapor deposition on a substrate prepared for the characteristic test, and then the shutter 222 is closed again. Then, the actual film thickness of the thin film formed by vapor deposition on the substrate prepared for the characteristic test is measured by a profilometer, and the actual film thickness of the thin film measured by the profilometer is compared with the film thickness of the thin film calculated by the film growth rate-measuring device 129 by using the film thickness monitor part (film thickness-computing part) to determine a correction factor for the film thickness calculated by the film growth rate-measuring device 129. After the determination of the correction factor, the film thickness of a thin film calculated by the film growth rate-measuring device 129 is multiplied by the correction factor using the film thickness monitor part (film thickness-computing part) to determine the actual film thickness of the thin film formed on the substrate 50 by vapor deposition. It is to be noted that when a film thickness is calculated by the film growth rate-measuring device 129, a film growth rate fluctuates. Therefore, a value obtained by multiplying each film growth rate by the time during which vapor deposition is carried out at this film growth rate is defined as a film thickness at this film growth rate, and the sum of the thus obtained film thicknesses is calculated by the film thickness monitor part (film thickness-computing part) to obtain a film thickness calculated by the film growth rate-measuring device 129.

It is to be noted that for the sake of simplification, a correction factor previously determined may be used for determining the actual film thickness of a thin film formed on the substrate 50, or a film thickness calculated by the film growth rate-measuring device 129 without using a correction factor may be used as it is.

By dividing the thus determined film thickness by the time required for forming a film having the film thickness (i.e., the time, during which the shutter 222 is opened, obtained from the control part 250 or the motor 223) using the film thickness monitor part (film thickness-computing part), it is possible to determine a film growth rate. It is to be noted that the film growth rate is not limited to one value but often varies within a certain range. Therefore, in reality, the variation range of the film growth rate is determined. The film thickness monitor part (film thickness-computing part) determines whether the calculated film growth rate (variation range of the film growth rate) lies within an allowable range or not. When the film thickness monitor part (film thickness-computing part) determines that the film growth rate exceeds the allowable range, appropriate measures are taken to reduce the kinetic energy of vapor-deposition particles under the control of the control part 250 by lowering the temperature of the material-heating cell 100 heated by the resistance heater 80, or by reducing the amount of a gas supplied from the fluid-supplying device 10, or by lowering the voltage of ion plating by the ionizer 30. On the other hand, when the film thickness monitor part (film thickness-computing part) determines that the film growth rate is lower than the allowable range, appropriate measures are taken to increase the kinetic energy of vapor-deposition particles under the control of the control part 250 by increasing the temperature of the material-heating cell 100 heated by the resistance heater 80, or by increasing the amount of a gas supplied from the fluid-supplying device 10, or by increasing the voltage of ion plating by the ionizer 30. When the film thickness monitor part (film thickness-computing part) determines that the film growth rate (variation range of the film growth rate) lies within the allowable range, the vapor-deposition coating process proceeds to step S4.

Then, in step S4, the XY stage device 230 is driven so that the end of a portion in the substrate 50 where a pattern is to be formed, that is, the start line of vapor-deposition coating is opposed to the nozzle tip portion 150 of the chamber 140 at a predetermined interval. From the viewpoint of controlling coating with accuracy, the predetermined interval is preferably, for example, about 0.1 mm or more but 50 mm or less. The reason for setting the predetermined interval to 0.1 mm or more is to prevent the contact between the substrate 50 and the nozzle tip portion 150 because the flatness of the substrate is about 0.1. If the predetermined interval exceeds 50 mm, there is a possibility that the atmosphere adversely affects the material discharged from the nozzle tip portion 150, so that it becomes difficult for the material to move straight ahead, and thus that is unfavorable.

Then, in step S5, the motor 223 is driven to rotationally shift the shutter 222 from the closed position II to the open position I, so that the ionized material 20 is discharged from the nozzle tip portion 150 toward the portion in the substrate 50 where a pattern is to be formed to start vapor-deposition coating. During the discharge of the material 20, driving of the XY stage device 230 is stopped to form a thin film having a predetermined thickness by vapor deposition on the portion in the substrate 50 where a pattern is to be formed.

It is to be noted that in the case of using a metal mask 180 as will be described later, the substrate 50 is moved in a substrate moving direction 90 by driving the XY stage device 230 while the material 20 is discharged from the nozzle tip portion 150 with the shutter 222 being opened, so that the nozzle tip portion 150 of the chamber 140 is relatively moved along a direction in which through holes 180a of the metal mask 180 to be described later are arranged (i.e., along the portion in the substrate 50 where a pattern is to be formed) to form a vapor-deposited coating film 55 having, for example, a dot pattern on the portion in the substrate 50 where a pattern is to be formed.

It is to be noted that the film growth rate is, for example, a few tens of nm/sec, and the thickness of the vapor-deposited coating film 55 is, for example, 100 nm.

Then, in step S6, the film thickness monitor part (film thickness-computing part) determines whether the vapor-deposited coating film 55 has a certain mass (thickness) or not. When the film thickness monitor part (film thickness-computing part) determines that the vapor-deposited coating film 55 has a certain mass, the vapor-deposition coating process proceeds to step S7. On the other hand, when the film thickness monitor part (film thickness-computing part) determines that the vapor-deposited coating film 55 does not have a certain mass, the vapor-deposition coating process is returned to step S6 to continue to form the vapor-deposited coating film 55.

In step S7, when the control part 250 receives a signal (i.e., a signal for indicating that the vapor-deposited coating film 55 has a certain mass) from the film thickness monitor part (film thickness-computing part), the motor 223 is driven under the control of the control part 250 to rotationally shift the shutter 222 from the open position I to the closed position II to stop the discharge of the ionized material 20 from the nozzle tip portion 150 toward the portion in the substrate 50 where a pattern is to be formed, so that vapor-deposition coating is completed.

Then, in step S8, the control part 250 determines whether or not the pattern of the material 20 has been completely formed on the portion in the substrate 50 where the pattern is to be formed. More specifically, the control part 250 determines whether or not vapor-deposition coating of not only one sheet of the substrate 50 but also a predetermined number of sheets of the substrate 50 has been thoroughly completed. When the control part 250 determines that vapor-deposition coating has been thoroughly completed, the vapor-deposition coating process proceeds to step S9. On the other hand, when the control part 250 determines that vapor-deposition coating has not yet been thoroughly completed, the vapor-deposition coating process is returned to step S4. It is to be noted that in a case where vapor-deposition coating of one sheet of the substrate 50 has been completed but vapor-deposition coating of another sheet of the substrate 50 has not yet been completed, the vapor-deposition coating process is returned to step S4 to change the substrate 50 to another one, and then the XY stage device 230 is driven to carry out step S4 to step S8 described above.

In step S9, the inflow of Ar gas or N₂ gas supplied from the fluid-supplying device 10 into the chamber 140 is stopped to complete a series of the steps of the vapor-deposition coating process.

According to the first embodiment, in a device production technique using the vapor deposition head apparatus 11 and the method of coating by vapor deposition according to the first embodiment of the present invention, it is possible to directly form a vapor-deposited coating film 55 on the substrate 50 through vapor deposition by the vapor deposition method using a high-performance low-molecular material even at atmospheric pressure without lowering material use efficiency (e.g., 50% or higher of material use efficiency can be achieved). In addition, by controlling the voltage of the power supply 40 applied to the nozzle part 120, it is possible to control the discharge diameter of the material 20 discharged from the nozzle tip portion 150.

As more specific example, it is possible to form a quadrilateral vapor-deposited coating film 55 of 140×280 pixels having RGB pixel having a size of 568 μm×189 μm per pixel for a 7-inch display by vapor deposition (in the case of a 100-inch display, 2000 cells×4000 cells).

It is to be noted that the flow of the ionized charged molecules 70 may be controlled from the outside of the nozzle part 120.

The present invention is not limited to the embodiment described above, and includes other various embodiments.

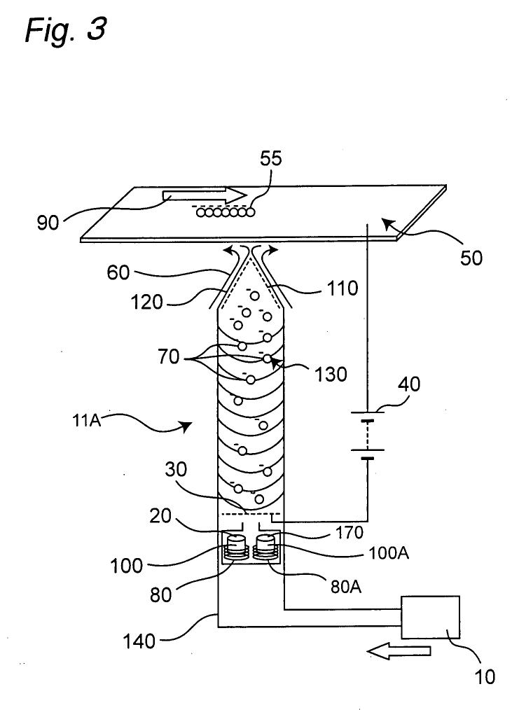

For example, although the vapor deposition head apparatus shown in FIG. 1A is designed to carry out vapor deposition of only the ionized organic material 20 as an example of a solid material, a variation of the first embodiment of the present invention may provide a vapor deposition head apparatus 11A having, in the chamber 140, the above-described material-heating cell 100 for heating the organic material 20 and a second material-heating cell 100A for heating an inorganic material 170 by a resistance heater 80A having the same structure as the resistance heater 80 provided for the material-heating cell 100 as shown in FIG. 3. In the case of using the vapor deposition head apparatus 11A, the organic material 20 and the inorganic material 170 may be vaporized by resistively heating the organic material 20 and the inorganic material 170 independently from each other and mixed at a certain ratio in the chamber 140 to ionize the mixture by one ionizer 30 to vapor-deposition-coat the organic material 20 and the inorganic material 170 on the substrate 50.

However, as in the case of the vapor deposition head apparatus 11 shown in FIG. 1A, the ionizer 30 may be provided in such a manner as shown in FIG. 3 to promote ionization.

Further, although the vapor deposition head apparatus 11 shown in FIG. 1A or FIG. 3 is designed to carry out vapor deposition of only the organic material 20 or a mixture of the organic material 20 and the inorganic material 170 at atmospheric pressure by increasing the pressure in the chamber 140, another variation of the first embodiment of the present invention (not shown) may be achieved by housing the substrate 50 and all the components of the vapor deposition head apparatus including the chamber 140 in a sealed room for coating to carry out vapor-deposition coating in the room for coating maintained at a low pressure by a vacuum device.

Further, although the vapor deposition head apparatus 11 shown in FIG. 1A has a tapered structure at only one portion in the nozzle part 120, still another variation of the first embodiment of the present invention may be achieved by providing two or more tapered structures stepwise to allow the ionized charged molecules 70 to more easily move straight ahead.

Further, in order to control the ionized charged molecules 70 so that the ionized charged molecules 70 can move straight ahead, the voltage of the power supply 40 applied to the chamber 140 may be changed in multistepwise so that the intensity of an electric field can be gradually increased from the side surface of the chamber 140 at a portion where the material-heating cell 100 is provided, toward the nozzle tip portion 150 of the nozzle part 120.

Further, although FIG. 1A shows the process of vaporizing the solid material 20 by the single vapor deposition head apparatus 11 to vapor-deposit the material 20 on the substrate 50, as shown in FIG. 6, yet another variation of the first embodiment of the present invention may be achieved by providing a plurality of the vapor deposition head apparatuses 11 shown in FIG. 1A in parallel. In this case, only required one or more of the vapor deposition head apparatuses 11 may be resistively heated to vaporize the material 20 and a fluid is supplied only to the one or more vapor deposition head apparatuses 11. Alternatively, the shutter(s) 222 of only required one or more of the vapor deposition head apparatuses 11 may be opened. In FIG. 6, detailed mechanisms such as the ionizer 30 used as an example of an ion accelerating mechanism and the power supply 40 used as an example of a mechanism for applying the same electric potential as the ions to the nozzle part 120 are not shown. In the case of providing a plurality of vapor deposition head apparatuses, it is preferred that an integrated control part 250A for integrally controlling the control parts 250 of all the vapor deposition head apparatuses 11 is further provided to control vapor-deposition coating carried out using only required one or more of the vapor deposition head apparatuses 11. By doing so, for example, it is possible to form a predetermined number of pixels of any one of the RGB colors at the same time by vapor deposition.

Further, although in FIG. 1A, the vapor deposition head apparatus 11 is fixed and the substrate 50 is moved using the XY stage device 230 to vapor-deposit the material 20 on the substrate 50, yet still another variation of the first embodiment of the present invention may be achieved by fixing the substrate 50 and moving the vapor deposition head apparatus 11 in the substrate moving direction 90 using the XY stage device.

### Second Embodiment

Hereinbelow, a vapor deposition head apparatus and a method of coating by vapor deposition which can be carried out by using the vapor deposition head apparatus, according to a second embodiment of the present invention will be described. The second embodiment will be described with reference to a case using a metal mask 180.

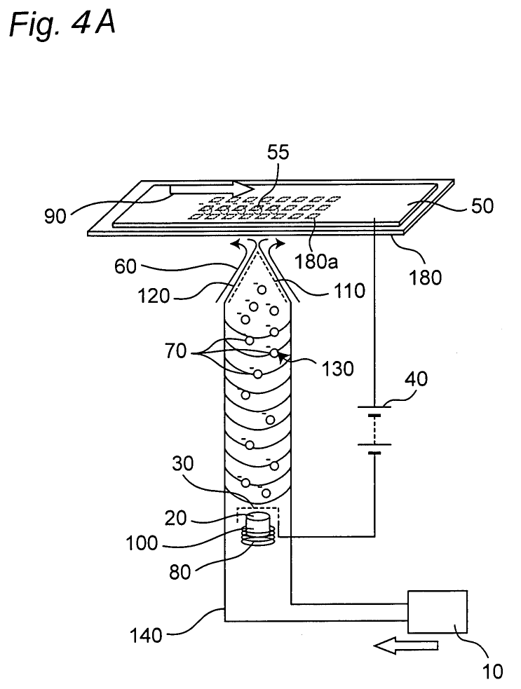

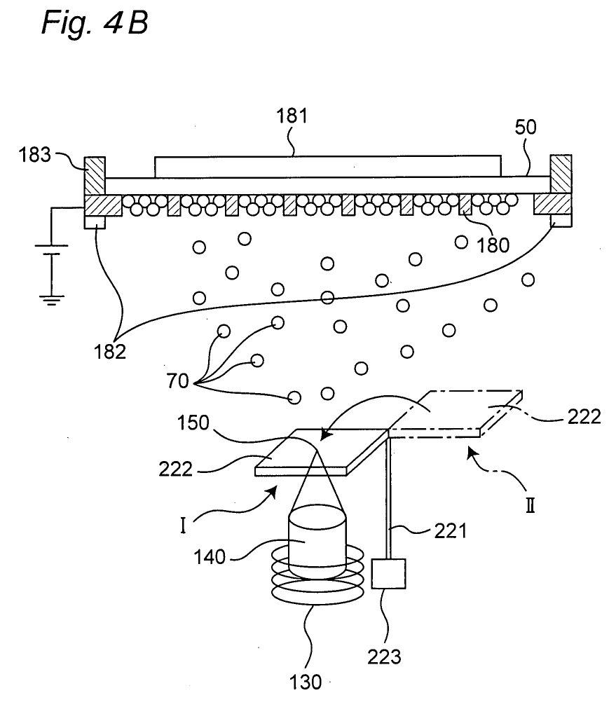

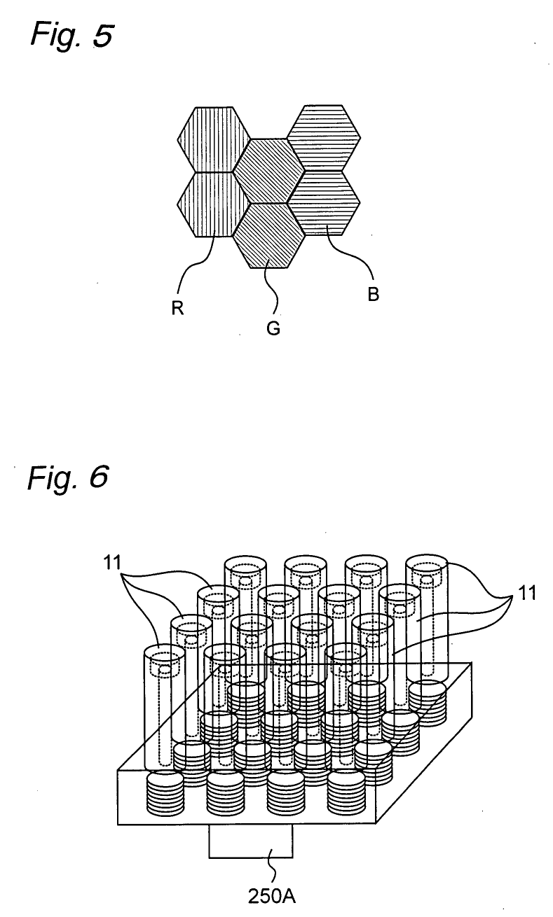

As shown in FIGS. 4A and 4B, the second embodiment uses the vapor deposition head apparatus 11 shown in FIG. 1A and the metal mask 180 provided between the substrate 50 and the vapor deposition head apparatus 11 provided under the substrate 50. The metal mask 180 is made of, for example, Invar (which is an alloy having a low thermal expansion coefficient at around room temperature), and has a thickness of, for example, 100 to 200 μm. The magnetic metal mask 180 is fixed onto the lower surface of the substrate 50 by, for example, the magnetic force of a magnet(s) 181 provided on the upper surface of the substrate 50. The substrate 50 itself is held by the XY stage device 230 with the use of a substrate support frame 183 having an L-shaped cross section and fixed to the XY stage device 230 by fixation screws 182. The metal mask 180 has through holes 180a. For example, each of the through holes 180a may be formed into a hexagonal shape to correspond to one pixel so that, as shown in FIG. 5, RGB pixels adjacent to one another can be formed by coating. The width of a dividing wall between adjacent pixels is, for example, about 10 to 20 μm.

In the case of carrying out ion plating, by applying the same electric potential as the electrification charges of the charged molecules 70 of the material 20 to the metal mask 180, it is possible to suppress the attachment of the charged molecules 70 of the material 20 to the metal mask 180. More specifically, the same electric potential as charged ions is applied to the metal mask 180 (i.e., the metal mask 180 is allowed to have the same electric charge in sign as that of the charged molecules 70 of the material 20), and as a result the charged ions (i.e., the charged molecules 70 of the material 20) are repelled by the metal mask 180 but come into contact with an unelectrified portion (i.e., a portion in the substrate 50 where a pattern is to be formed) and are then vapor-deposition-coated thereon. In a case where an organic material and an inorganic material are resistively heated with resistance heating and vaporized and mixed at the same time using the vapor deposition head apparatus 11A as shown in FIG. 3, and an ionized mixture of the organic and inorganic materials may be vapor-deposition-coated on the substrate 50 with the use of the metal mask 180 as shown in FIG. 4A. Also in this case, by applying the same electric potential as ionized charges to the metal mask 180 itself (i.e., by allowing the metal mask 180 to have the same electric charge in sign as that of ionized charges), it is possible to suppress the occurrence of a phenomenon in which the vapor-deposition material is unnecessarily attached to the metal mask 180, thereby increasing material use efficiency.

After the completion of vapor-deposition coating, the metal mask 180 can be separated from the substrate 50 by removing the magnet(s) 181 from the substrate 50.

As described above, according to the second embodiment, the use of the metal mask 180 makes it possible to form a pattern on the substrate 50 by vapor deposition with accuracy. Further, by making the size of the through hole 180a of the metal mask 180 smaller than the diameter of the aperture of the nozzle tip portion 150 and using the metal mask 180, it is possible to form a thin film (pattern) having a size smaller than the diameter of the aperture of the nozzle tip portion 150 on the substrate 50.

By properly combining the arbitrary embodiments of the aforementioned various embodiments, the effects possessed by the embodiments can be produced.

### INDUSTRIAL APPLICABILITY

The vapor deposition head apparatus and the method of coating by vapor deposition according to the present invention can realize a vapor-deposition coating technique using a vapor deposition head which can be used in the fields of organic semiconductor devices, organic EL (Electro Luminescence) devices, organic solar batteries, and the like. According to the vapor-deposition coating technique, it is possible to directly form a coating film on an object to be coated, such as a substrate, by vapor deposition even at atmospheric pressure by heating a solid material to vaporize the solid material, applying electric charge to the vaporized material, and applying the same voltage as the electrification charges to the nozzle part to control the shape of the vapor-deposition material discharged from the nozzle part.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1. A vapor deposition head apparatus comprising:
a chamber having a nozzle part at its one end;
a material-heating cell, provided in the chamber, for holding a solid material;
a resistance-heating part for heating the material-heating cell;
a fluid-supplying device connected to an other end of the chamber to supply a fluid from an other end side of the chamber into the chamber to guide the material vaporized from the material-heating cell heated by the resistance-heating part to the nozzle part of the chamber to discharge the material from the nozzle part; and
an air-blowing part for blowing a gas for controlling vapor deposition material straight movement, outside the nozzle part of the chamber toward a tip of the nozzle part to control the material discharged from the nozzle part so that the material can move straight ahead.

2. The vapor deposition head apparatus according to claim 1, further comprising:
an ionizer for ionizing the solid material vaporized from the material-heating cell heated by the resistance-heating part, the ionizer being provided between the nozzle part and the material-heating cell; and
an electric potential-applying part for applying an electric potential different from that of a charge of the ionized material to an object onto which the material discharged from the nozzle part of the chamber is to be vapor-deposited.

3. The vapor deposition head apparatus according to claim 1, wherein the electric potential-applying part applies the same electric potential as the charge of the ionized material to the chamber.

4. The vapor deposition head apparatus according to claim 1, further comprising a shutter for opening and closing an aperture of the nozzle part of the chamber.

5. The vapor deposition head apparatus according to claim 3, further comprising a shutter for opening and closing an aperture of the nozzle part of the chamber.

6. The vapor deposition head apparatus according to claim 1, wherein
the material-heating cell functions as a first material-heating cell for holding an organic material as the solid material and the resistance-heating part functions as a first resistance-heating part for heating the first material-heating cell to vaporize the organic material,
the vapor deposition head apparatus further comprising:
a second material-heating cell provided in the chamber for holding an inorganic material as the solid material; and
a second resistance-heating part for heating the second material-heating cell, wherein
the second material-heating cell is heated by the second resistance-heating part to vaporize the inorganic material, and
the vaporized organic material and the vaporized inorganic material are mixed at a certain ratio in the chamber and are then discharged from the nozzle part of the chamber.

7. A method of coating by vapor deposition comprising:
heating a material-heating cell provided in a chamber, and having a nozzle part at its one end, for holding a solid material; and
supplying a fluid from an other end side of the chamber toward the nozzle part of the chamber to guide the material vaporized from the heated material-heating cell to the nozzle part to discharge the material from the nozzle part, blowing a gas for controlling a vapor-deposition material straight movement, outside the nozzle part of the chamber toward a tip of the nozzle part to control the material discharged from the nozzle part so that the material can move straight ahead.

8. The method of coating by vapor deposition according to claim 7, wherein when the material vaporized from the material-heating cell is discharged from the nozzle part, the solid material vaporized from the heated material-heating cell is ionized between the nozzle part and the material-heating cell and an electric potential different from that of a charge of the ionized material is applied to an object onto which the material discharged from the nozzle part of the chamber is to be vapor-deposited.

9. The method of coating by vapor deposition according to claim 7, wherein when the material vaporized from the material-heating cell is discharged from the nozzle part, the same electric potential as the charge of the ionized material is applied to the chamber.

10. The method of coating by vapor deposition according to claim 7, wherein when the material vaporized from the material-heating cell is discharged from the nozzle part, start and stop of discharge of the material from the nozzle part is controlled by opening and closing an aperture of the nozzle part of the chamber using a shutter.

11. The method of coating by vapor deposition according to claim 9, wherein when the material vaporized from the material-heating cell is discharged from the nozzle part, start and stop of discharge of the material from the nozzle part is controlled by opening and closing an aperture of the nozzle part of the chamber using a shutter.

12. The method of coating by vapor deposition according to claim 7, wherein when the material-heating cell for holding the solid material is heated, an organic material and an inorganic material are heated, and when the material vaporized from the material-heating cell is discharged from the nozzle part, the organic material vaporized by heating and the inorganic material vaporized by heating are mixed at a certain ratio in the chamber and discharged from the nozzle part of the chamber.
